(19) United States
(12) Patent Application Publication
(10) Pub. No.: US 2026/0368382 A1
(43) Pub. Date: Nov. 19, 2026

(54) GENERATING A SPATIAL MODEL OF A FACILITY

(71) Applicant: Honeywell International Inc., Charlotte, NC (US)

(72) Inventors: Rajesh Kulandaivel Sankarapandian, Cumming, GA (US); Veeranagegowda Shivalingappa, Bengaluru (IN); Agniraj Chatterji, Bengaluru (IN); Sumanth Pachipulusu Lingesh, Bengaluru (IN); R. Dhawan Kumar, Hyderabad (IN)

(21) Appl. No.: 19/210,419

(22) Filed: May 16, 2025

(51) Int. Cl. G06F 30/13; G06F 30/12; G06F 30/27

(52) U.S. Cl. CPC G06F 30/13; G06F 30/12; G06F 30/27

(57) ABSTRACT

Devices, methods, and systems for generating a spatial model of a facility are described herein. One method includes uploading, to a computing device, facility information associated with a facility including facility layout information for the facility and technical asset information associated with devices in the facility, analyzing, by a generative artificial intelligence (AI) model hosted by the computing device, the facility layout information and the technical asset information, extracting, by the generative AI model, spatial hierarchy data and object data from the analyzed facility layout information and technical asset information, generating, by the generative AI model, a spatial model of the facility including instances for the spatial model using the spatial hierarchy data and the object data, and integrating, by the computing device, the spatial model of the facility into a building asset management system of the facility.

### TECHNICAL FIELD

The present disclosure relates generally to devices, methods, and systems for generating a spatial model of a facility.

### BACKGROUND

Virtual modeling of facilities has become an important part of facility management. These virtual spatial models can serve as digital representations of real-world facilities that can comprise one or more than one building associated therewith. Spatial models of facilities can be utilized, for example, in monitoring asset performance of the facility, health of the facility, and/or for incident management, among other examples.

### BRIEF DESCRIPTION OF THE DRAWINGS

FIG. 1 illustrates an example of a system for generating a spatial model of a facility in accordance with one or more embodiments.

FIG. 2 illustrates an example of a user interface displaying a spatial model in accordance with one or more embodiments.

FIG. 3 illustrates an example of a user interface displaying a technical diagram included as facility layout information for generating a spatial model of a facility in accordance with one or more embodiments.

FIG. 4 illustrates an example of a user interface displaying technical diagram included as facility layout information for generating a spatial model of a facility in accordance with one or more embodiments.

FIG. 5 illustrates an example of a method for generating a spatial model of a facility in accordance with one or more embodiments.

FIG. 6 is an example of a computing device for generating a spatial model of a facility in accordance with one or more embodiments.

### DETAILED DESCRIPTION

Devices, methods, and systems for generating a spatial model of a facility are described herein. One method includes uploading, to a computing device, facility information associated with a facility, analyzing, by a generative artificial intelligence (AI) model hosted by the computing device, the facility layout information and the technical asset information, extracting, by the generative AI model, spatial hierarchy data and object data from the analyzed facility layout information and technical asset information, generating, by the generative AI model, a spatial model of the facility including instances for the spatial model using the spatial hierarchy data and the object data, and integrating, by the computing device, the spatial model of the facility into a building asset management system of the facility.

As mentioned above, spatial models can serve as digital representations of real-world facilities. As such, a spatial model can include multiple layers of information. For example, a spatial model can accurately represent three-dimensional (3D) geometric data such as facility layout information that defines the shape, dimensions, and spatial relationships between elements such as walls, floors, ceilings, windows, doors, roofs, etc. However, spatial models can include further technical asset information that accurately represents technical systems in the facility, including mechanical systems, electrical systems, plumbing systems, and/or other engineering elements.

Utilizing both the facility layout information and technical asset information, a spatial model can accurately and holistically represent a facility, such as a building/buildings within the facility. Given the depth and breadth of the spatial model, a facility can be accurately represented in the spatial model for different use cases as mentioned above.

While a spatial model of a facility as described above can accurately and holistically represent a facility, creating such a spatial model can be a laborious task. For example, a facility such as a hospital can comprise a variety of complex spaces (e.g., different floors, wings, wards, rooms, operating rooms, laboratories, etc.). In order to accurately model such a facility, each of the elements that make up the facility have to be meticulously understood and replicated. For example, facility layout information has to be accurately captured and modeled, through thorough cross-referencing of numerous documents and diagrams (e.g., architectural layouts, building plans, engineering drawings, etc.). In addition, technical asset information has to also be accurately captured and modeled, ensuring the building systems are correctly defined, placed, and interconnected to one another, which also would include thorough cross-referencing of numerous documents and diagrams (e.g., engineering drawings, electrical/mechanical/plumbing layouts, structural information, etc.). Because of the depth and breadth of the spatial model, manually modeling facilities can increase a likelihood of mistakes, leading to potential inefficiencies and inaccuracies in the generated spatial model.

Generating a spatial model of a facility according to the disclosure, however, can allow for a simplified and accurate modeling approach to generating spatial models, as compared with previous approaches. Utilizing generative artificial intelligence (AI) techniques, facility information associated with a facility can be uploaded to a generative AI model. Facility information can include facility layout information and technical asset information associated with devices in the facility.

For example, a user can upload facility layout information and technical asset information. This facility layout information can include floor plans, building drawings (e.g., architectural, electrical, mechanical, plumbing, structural, etc.), building information models (BIM), human-machine interface (HMI) graphics, and/or any other type of facility information. The technical asset information can include project documents for the facility devices.

The generative AI model can analyze the facility layout information and the technical asset information and extract spatial hierarchy data and object data according to various machine learning techniques. For example, the generative AI model can be a large language model that can utilize natural language processing and/or image recognition techniques in order to analyze and extract information from the facility information provided to the generative AI model and can extract spatial hierarchy data and object data. The spatial hierarchy data can include models of spaces in the facility that can include the spaces in the facility, the names of the spaces in the facility, the space types of the spaces in the facility, the dimensions of the spaces in the facility, and the locational relationships between the spaces in the facility. Additionally, the object data can include the assets in the facility, the names of the assets in the facility, the types of assets in the facility, and relational information for the assets in the facility.

Using the extracted spatial hierarchy data and object data, the generative AI model can generate the spatial model, including instances for the spatial model (e.g., the space and asset names, types, etc.). Additionally, the generative AI model can perform an error analysis on the generated spatial model to highlight portions of the model that may be incomplete or missing. A user can accordingly review the spatial model and provide further information and/or corrections to the model where appropriate. During these steps, the generative AI model can retrain itself in order to continuously improve upon itself. Such an approach can allow for a streamlined development of spatial models while reducing the time and error associated with modeling spatial models, as compared with previous approaches.

In the following detailed description, reference is made to the accompanying drawings that form a part hereof. The drawings show by way of illustration how one or more embodiments of the disclosure may be practiced.

These embodiments are described in sufficient detail to enable those of ordinary skill in the art to practice one or more embodiments of this disclosure. It is to be understood that other embodiments may be utilized and that mechanical, electrical, and/or process changes may be made without departing from the scope of the present disclosure.

As will be appreciated, elements shown in the various embodiments herein can be added, exchanged, combined, and/or eliminated so as to provide a number of additional embodiments of the present disclosure. The proportion and the relative scale of the elements provided in the figures are intended to illustrate the embodiments of the present disclosure and should not be taken in a limiting sense.

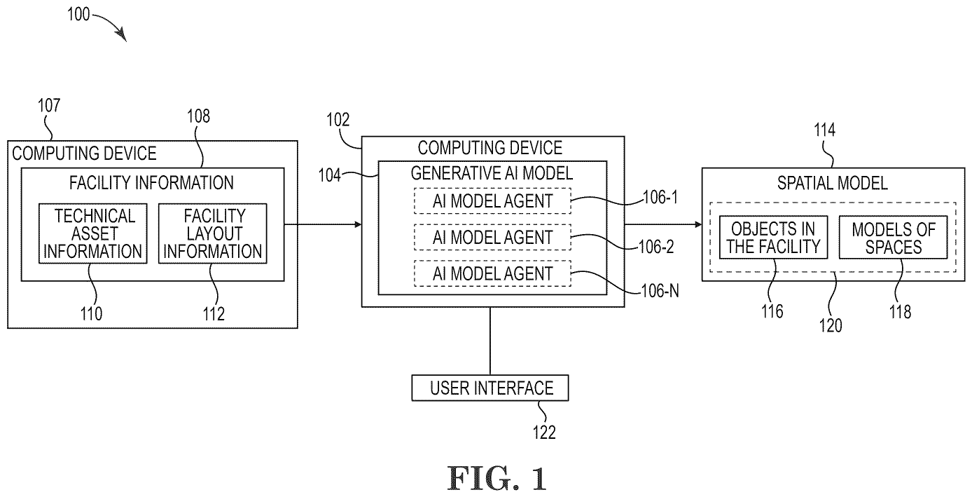

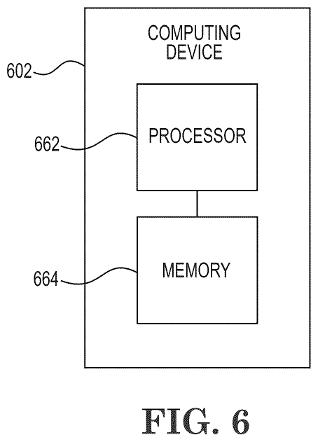

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 602 in FIG. 6.

As used herein, “a”, “an”, or “a number of” something can refer to one or more such things, while “a plurality of” something can refer to more than one such things. For example, “a number of components” can refer to one or more components, while “a plurality of components” can refer to more than one component. Additionally, the designator “N”, as used herein, particularly with respect to reference numerals in the drawings, indicates that a number of the particular feature so designated can be included with a number of embodiments of the present disclosure.

FIG. 1 illustrates an example of a system 100 for generating a spatial model of a facility in accordance with one or more embodiments. As illustrated in FIG. 1, the system 100 can include a computing device 102, facility information 108, and a spatial model 114.

As mentioned above, spatial models can serve as digital representations of real-world facilities. Such facilities can include, for example, a building, a campus including multiple buildings, etc. Examples of such buildings may include an office building, a stadium, a hospital, etc. The spatial models of such facilities can allow for monitoring of asset performance of the facility, health of the facility, and/or incident management, among other examples.

In order for the spatial model to accurately reflect the facility, the spatial model has to be generated according to the specifications of the real-world facility which it is to represent. By providing the generative AI model 104 the facility information 108, the generative AI model 104 can generate the spatial model 114 of the facility easily and accurately, as is further described herein.

As illustrated in FIG. 1, the system 100 can include the computing device 102. As used herein, the term “computing device” refers to an electronic system having a processing resource, memory resource, and/or an application-specific integrated circuit (ASIC) that can process information. Examples of computing devices can include, for instance, a laptop computer, a notebook computer, a desktop computer, a server, an All-In-One (AIO) computing device, networking equipment (e.g., router, switch, etc.), and/or a mobile device, among other types of computing devices. As used herein, a mobile device can include devices that are (or can be) carried and/or worn by a user. For example, a mobile device can be a phone (e.g., a smart phone), a tablet, a personal digital assistant (PDA), smart glasses, and/or a wrist-worn device (e.g., a smart watch), among other types of mobile devices.

The computing device 102 can be a cloud computing device. For example, the computing device 102 can be a cloud computing device included as part of a cloud-computing environment. For instance, the cloud computing device can be a computing device operating as part of a cloud computing environment remotely located from computing device 107 and can receive facility information 108 from computing device 107 via a network relationship (not shown in FIG. 1 for simplicity and so as not to obscure embodiments of the disclosure).

The computing device 107 can be connected to the computing device 102 via a wired and/or wireless network relationship. Examples of such a network relationship can include a local area network (LAN), wide area network (WAN), personal area network (PAN), a distributed computing environment (e.g., a cloud computing environment), storage area network (SAN), Metropolitan area network (MAN), a cellular communications network, Long Term Evolution (LTE), visible light communication (VLC), Bluetooth, Worldwide Interoperability for Microwave Access (WiMAX), Near Field Communication (NFC), infrared (IR) communication, Public Switched Telephone Network (PSTN), radio waves, and/or the Internet, among other types of network relationships.

Additionally, the system 100 can include a user interface 122. For example, the user interface 122 can display the spatial model 114 (e.g., as is further described herein) via a display. A user (e.g., operator) of a computing device (e.g., computing device 107, computing device 102, and/or any other computing device) can interact with the computing device via user interface 122. For example, user interface 122 can provide (e.g., display and/or present) information to the user of computing device, and/or receive information from (e.g., input by) the user of computing device. For instance, in some embodiments, user interface 122 can be a graphical user interface (GUI) that can provide information to and/or receive information from the user of computing device 102. The display can be, for instance, a touchscreen (e.g., the GUI can include touch-screen capabilities). Alternatively, a display can include a television, computer monitor, mobile device screen, other type of display device, or any combination thereof, connected to the computing device and configured to receive a video signal output from the computing device. For example, the user interface 122 can display the spatial model 114, receive inputs related to the spatial model, etc., as is further described herein.

In order to generate the spatial model 114, facility information 108 can be provided (e.g., uploaded) to the computing device 102. As used herein, the term “facility information” refers to physical and/or functional characteristics of a facility, and/or building, and/or devices included therein both. For example, facility information 108 can be uploaded to the computing device 102 by a user of the computing device 107. Facility information can be in the form of scans, images, and/or other computing device file types, and can include PDF, PNG, JPG, human-machine interface (HMI), building information model (BIM), computer-assisted design (CAD), and/or other file types. Such a user may intend to cause generation of a spatial model for a facility and as such, can upload the facility information 108 in whichever format the facility information is in to the computing device 102 as is further described herein.

As mentioned above, facility information 108 can include physical and/or functional characteristics of the facility, and/or physical and/or functional characteristics of devices included therein. For example, facility information 108 can include facility layout information 112 for the facility and/or technical asset information 110 associated with devices in the facility, as are further described herein.

As used herein, facility layout information refers to the arrangement of physical barriers and/or physical resources within a facility. Facility layout information 112 can include BIMs for the facility, HMI graphics for the facility, CAD files, building plans for the facility such as instrumentation diagrams and/or technical drawings (e.g., architectural, electrical, mechanical, engineering, plumbing, structural, security, etc.), etc. Accordingly, the facility layout information 112 can represent the spaces in the facility, the names of the spaces in the facility, space types in the facility, as well as the locational relationships between the spaces of the facility.

As used herein, technical asset information associated with devices in the facility refers to characteristics and specifications of physical devices in the facility. Technical asset information 110 can include project documents for devices in the facility. Devices in the facility can include, for instance, electrical devices (e.g., wiring, switches, relays, etc.), mechanical devices (e.g., pumps, compressors, fans, etc.), plumbing (e.g., pumps, valves, piping, etc.), security (e.g., alarm devices, cameras, sensors (heat, fire motion, etc.), etc.), among other devices and types of devices in the facility. Accordingly, the technical asset information 110 can represent the assets in the facility (e.g., the devices), the names of the assets, the types of assets, operational information for the assets (e.g., manufacturer, operational attributes for the devices, etc.), as well as relational information for the assets in the facility, such as the connections therebetween.

As an example, a user can upload facility information 108 for a hospital to the computing device 102 (e.g., via computing device 107). The facility information 108 can include facility layout information 112 for the hospital included in a BIM that illustrate the layout of the hospital including five buildings, the number of floors of each of the five buildings, the specific space layouts of each of the floors of each of the five buildings (e.g., showing operating rooms, laboratories, patient consultation rooms, waiting rooms, hospital rooms, offices, conference rooms, etc., as well as their sizes and relative locations in each of the floors of each of the five buildings), technical drawings that illustrate the architectural details of each space in each floor of each of the five buildings, electrical drawings that provide a visual representation of the electrical devices and connections of the electrical system on each space in each floor of each of the five buildings as well as connections between floors/buildings (e.g., electrical wiring, computer networking wiring, telephone wiring, etc. as well as the type of wiring used), mechanical drawings that provide a visual representation of mechanical devices and connections therebetween of the mechanical system in each space in each floor of each of the five buildings and locational relationships therebetween (e.g., the pumps, compressors, fans, ducting, their locations, connections therebetween, etc.), plumbing drawings that provide a visual representation of plumbing devices and connections therebetween of the plumbing system in each space in each floor of each of the five buildings and locational relationships therebetween (e.g., the pumps, valves, piping, connections therebetween, etc.), security drawings that provide a visual representation of security devices of the security system in each space in each floor of each of the five buildings and locational relationships therebetween (e.g., the alarm devices, cameras, sensors, connections therebetween, etc.), among other types of facility information 108.

The facility layout information 112 described above can be in any file format. For example, the building plans, which may be technical drawings, may be scanned and saved as a picture file format (e.g., JPG), as a user has scanned the technical drawings from paper drawings showing the same. In some examples, the building plans, such as a plumbing instrumentation diagram, may be in a picture format (e.g., PNG) as it is a screen shot of an HMI. As another example, the building plans may be included in a BIM. In some examples, the building plans may be in a mixture of different file formats (e.g., JPG, BIM, PDF, PNG, etc.). The user can upload any and/or all of this facility layout information 112 to the computing device 102.

Continuing with the example above, the user can further upload technical asset information 110 to the computing device 102 (e.g., via computing device 107). The technical asset information 110 can include project documents for the devices in the five buildings of the hospital. The project documents can include, for instance, characteristics and specifications of the physical devices included in the hospital, such as the pumps, compressors, fans, valves, alarm devices, cameras, sensors, etc. The characteristics and specifications of the physical devices can include operating parameters that describe how a device functions and can be adjusted or controlled during operation (e.g., temperature, pressure, flow rate, voltage, current, etc.). For example, the operating parameters of each of the pumps can be included as technical asset information 110 (e.g., flow rate, capacity, head, power, efficiency, etc.). In some examples, some facilities such as a hospital may have other specialized equipment which can also be included, such as specialized surgical devices, x-ray devices, magnetic resonance imaging (MRI) devices, etc. Such devices may also be included in the technical asset information 110 and can be included in the facility layout information 112 described above.

The technical asset information 110 described above can be in any file format. For example, the project documents may be scanned and saved as a picture file format (e.g., JPG), as a user has scanned the project documents from paper drawings showing the same. In some examples, the project documents, such as a pumps operating manual, may be in a portable document format (e.g., PDF) as it was downloaded from a manufacturer's website. As another example, the project documents may be included in a BIM. In some examples, the project documents may be in a mixture of different file formats (e.g., JPG, BIM, PDF, PNG, etc.). The user can upload any and/or all of this technical asset information 110 to the computing device 102.

As illustrated in FIG. 1, the computing device 102 can include (e.g., host) a generative AI model 104. As used herein, a generative AI model refers to an algorithm or series of algorithms that learn underlying patterns and/or structures in training data using statistical analysis and mathematical optimization and use those patterns and/or structures to produce new data based on an input, where the input can be in the form of a natural language prompt. Learning the underlying patterns and/or structures in the training data refers to analyzing the training data and adjusting parameters in the generative AI model in order to minimize error in the statistical analysis.

The generative AI model 104 can be, accordingly, a pre-trained model. For example, the generative AI model 104 can be trained utilizing training data. The training data can include types of facility information, including technical asset information and facility layout information of other facilities. The training data can allow the generative AI model 104 to be trained to analyze facility information provided to it. In some examples, the generative AI model 104 can be a large language model (LLM).

Accordingly, once the user uploads the facility information 108 to the computing device 102, the generative AI model 104 can analyze the facility layout information 112 and the technical asset information 110. The generative AI model 104 can analyze the facility layout information 112 and the technical asset information 110 using natural language processing techniques and/or image recognition techniques.

For example, the generative AI model 104 can analyze the facility layout information 112 in order to determine spaces in the facility, names of spaces in the facility, space types of the spaces in the facility, dimensions of the spaces in the facility, and/or locational relationships between the spaces in the facility. For instance, the facility layout information 112 uploaded by the user can include a BIM of a hospital, as well as technical drawings and instrumentation diagrams. The generative AI model 104 can analyze the BIM, technical drawings, and instrumentation diagrams to determine a number of buildings associated with the hospital (e.g., five), the number of floors in each building, the spaces in each of the buildings, the names of the spaces in the buildings (e.g., Conference Room 1, Operating Room 1, Patient Recovery Room 5, etc.), the types of spaces (e.g., operating rooms, laboratories, patient consultation rooms, waiting rooms, hospital rooms, offices, conference rooms, etc.), dimensions of the spaces, and/or locational relationships between the spaces (e.g., the locational relationships between the spaces).

Additionally, the generative AI model 104 can analyze the technical asset information 110 to determine assets in the facility, the names of assets in the facility, the types of assets in the facility, and/or relational information for the assets in the facility. For instance, the technical asset information 110 uploaded by a user can include project documents for the devices in the five buildings of the hospital, including characteristics and specifications of the physical devices included in the hospital such as the pumps, compressors, fans, valves, alarm devices, cameras, sensors, etc. The generative AI model 104 can analyze the project documents to determine the assets in the facility (e.g., the physical devices in the hospital), the names of the assets in the facility (e.g., Pump 1, Compressor 4, Air Handling Unit 5, etc.), the types of assets in the facility (e.g., pumps, compressors, fans, valves, alarm devices, cameras, sensors, etc.), relational information for the assets in the facility (e.g., Pump 1 is associated with piping servicing operating room 1, Valve 2 is connected to piping associated with Pump 1, etc.), and/or operating parameters (e.g., Pump 1 has an associated flow rate, capacity, head, power, efficiency, etc.).

As mentioned above, the generative AI model 104 can analyze the uploaded facility layout information 112 and the technical asset information 110 using natural language processing techniques and/or image recognition techniques. The generative AI model 104 can extract spatial hierarchy data and object data from the analyzed facility layout information 112 and the technical asset information 110, respectively.

Extracting the spatial hierarchy data can include identifying spaces in the facility, labeling spaces in the facility, categorizing space types of the spaces in the facility, and/or determining locational relationships between the identified spaces in the facility. For example, the generative AI model 104 can identify spaces in the facility (e.g., determine five buildings are associated with the hospital, the number of floors of each building, and the spaces in each of the buildings on each of the floors), label the spaces in the facility (e.g., Conference Room 1, Operating Room 1, Patient Recovery Room 5, etc.), categorize space types of the spaces where appropriate (e.g., operating rooms, laboratories, patient consultation rooms, waiting rooms, hospital rooms, offices, conference rooms, etc.), and determining locational relationships between the identified spaces in the facility (e.g., Office 1 is adjacent to Office 2 and located on floor 3 of building 2, Floor 2 of Building 1 is located above Floor 1 of Building 1, etc.).

Extracting the object data can include identifying assets in the facility, labeling assets in the facility, categorizing asset types in the facility, determining locational relationships between the identified assets and identified spaces in the facility from the spatial hierarchy data, and/or determining connection relationships between the identified assets. For example, the generative AI model 104 can identify assets in the facility (e.g., pumps, compressors, fans, valves, alarm devices, cameras, sensors, etc.), label the assets in the facility (e.g., Pump 1, Compressor 4, Air Handling Unit 5, etc.), categorize the asset types in the facility, such as by device type (e.g., pumps, compressors, fans, valves, alarm devices, cameras, sensors, etc.), asset type (e.g., heating, ventilation, air conditioning (HVAC), plumbing, electrical, security, etc.), etc., determine locational relationships between the identified assets and identified spaces from the spatial hierarchy data (e.g., Pump 1 is associated with piping servicing operating room 1, etc.), and/or determining connection relationships between the identified assets (e.g., Valve 2 is connected to piping associated with Pump 1, etc.).

Accordingly, the generative AI model 104 can generate the spatial model 114 of the facility including instances for the spatial model using the spatial hierarchy data and the object data. The spatial model 114 can include models of spaces in the facility, objects in the facility, and a template for spaces in the facility, as is further described herein. The spatial model 114 can accurately represent the facility it is modeled after. For example, the spatial model 114 can accurately represent the 3D geometric data associated with the hospital (e.g., according to the facility layout information 112) such as the shape, dimensions, and spatial relationships between walls, floors ceilings, windows, doors, roofs, etc., as well as the technical systems in the hospital including the devices and interconnected relationships that make up the architectural, electrical, mechanical, engineering, plumbing, structural, security, and/or other systems in the hospital, as is further described herein.

As mentioned above, the spatial model 114 can include models of spaces 118 in the facility. The models of spaces can include instances for the spatial model 114 that can include the spaces in the facility, the names of the spaces in the facility, the space types of the facility, the dimensions of the spaces in the facility, and/or the locational relationships between the spaces in the facility. For example, the models of spaces 118 in the spatial model 114 can include the computing instances for the spaces in the facility (e.g., five buildings are associated with the hospital, the number of floors of each building, and the spaces in each of the buildings on each of the floors), the names of the spaces in the facility (e.g., Conference Room 1, Operating Room 1, Patient Recovery Room 5, etc.), the space types of the spaces where appropriate (e.g., operating rooms, laboratories, patient consultation rooms, waiting rooms, hospital rooms, offices, conference rooms, etc.), the dimensions of the spaces in the facility (e.g., the dimensions of the operating rooms, laboratories, patient consultation rooms, waiting rooms, hospital rooms, offices, conference rooms, etc.), and the locational relationships between the identified spaces in the facility (e.g., Office 1 is adjacent to Office 2 and located on floor 3 of building 2, Floor 2 of Building 1 is located above Floor 1 of Building 1, etc.). Accordingly, the spatial hierarchy data is extracted such that the generative AI model 104 generates the spatial model 114 to include models of spaces 118 that include the above information.

The spatial model 114 can further include objects in the facility 116. The objects in the facility 116 can include instances for the spatial model 114 that can include the assets in the facility, the names of the assets in the facility, the types of assets in the facility, and/or the relational information for the assets in the facility. For example, the objects in the facility 116 can include the assets in the facility (e.g., pumps, compressors, fans, valves, alarm devices, cameras, sensors, etc.), the names of the assets in the facility (e.g., Pump 1, Compressor 4, Air Handling Unit 5, etc.), the types of assets in the facility (e.g., pumps, compressors, fans, valves, alarm devices, cameras, sensors, etc., and/or more broadly heating, ventilation, air conditioning (HVAC), plumbing, electrical, security, etc.), and the locational relationships between the identified assets (e.g., Pump 1 is associated with piping servicing operating room 1, Valve 2 is connected to piping associated with Pump 1, etc.). Accordingly, the object data is extracted such that the generative AI model 104 generates the spatial model 114 to include objects in the facility 116 that include the above information.

As illustrated in FIG. 1, the spatial model 114 can include a template 120 for a space in the facility. As used herein, a template can be a portion of the spatial model 114 (e.g., generating the spatial model can include generating one or more templates for the spatial model). The template 120 can be a computing object among a plurality of computing objects (e.g., a plurality of templates) that comprise the spatial model 114. In some examples, the spatial model 114 can comprise the plurality of templates, where each template represents a space in the facility. The template 120 can include, for instance, a model of a space and objects in the space. Accordingly, the generative AI model 104 can generate the template 120 for a space in the facility, and/or for some or all of the spaces in the facility.

For example, the template 120 can be one template among a plurality of templates (e.g., not illustrated in FIG. 1) that comprise the spatial model 114 for the hospital. The template 120 can be for an operating room in the hospital, where the template 120 includes a model of the operating room (e.g., models of spaces 118) that defines the space in the hospital (e.g., the dimensions, the location, it's location relative to other spaces in the hospital, etc.), the type of space (e.g., an operating room), etc. Additionally, the template 120 can include objects in the facility 116 including identified assets associated with (e.g.,. that service, are connected to, and/or are located in) the operating room, the labels of the assets, asset types, and/or locational relationships with other objects in the operating room and/or other objects in the hospital. Accordingly, the templates 120 can compartmentalize the spaces within the spatial model 114 and allow for a user to review and/or analyze the completeness and accuracy of the spatial model 114 generated by the generative AI model 104, as is further described herein.

As mentioned above, the generative AI model 104 is a pre-trained model. However, the generative AI model 104 can be continuously retrained in order to continually improve upon the accuracy of the outputs from the generative AI model 104. For example, once the generative AI model 104 has generated the spatial model 114, the generative AI model 104 can retrain itself using the spatial model 114 in order to improve upon the accuracy of future generated spatial models.

In some examples, a user can provide an input to a user interface 122 in order to correct an inaccuracy in the spatial model 114 and/or provide additional information to increase the completeness of the generated spatial model 114, as is further described herein. In such an instance, the generative AI model 114 can correct the spatial model and further retrain itself based on the correction (e.g., using the input that specifies the correction to the spatial model 114).

In some examples, the generative AI model 104 can include a plurality of generative AI model agents 106-1, 106-2, 106-N, which may be referred to herein collectively as generative AI model agents 106. The plurality of generative AI model agents 106 can be different large language models, small language models, and/or combinations thereof and can perform different tasks as sub-models as they can be trained on different training data sets for particular tasks.

For instance, the generative AI model agent 106-1 can analyze the facility layout information 112 and the technical asset information 110, as described above. The generative AI model agent 106-2 can extract the spatial hierarchy data and the technical asset information from the analyzed facility layout information and technical asset information, and the generative AI model agent 106-N can generate the spatial model 114 using the extracted spatial hierarchy data and the object data. Distributing different tasks to different generative AI model agents 106 (e.g., sub-models) can allow for efficient resource utilization.

Accordingly, once the spatial model 114 is generated, the computing device 102 can integrate (e.g., implement) the spatial model 114 into a building asset management system of the facility. The building asset management system can allow for monitoring asset performance of the facility, health of the facility, and/or for incident management, among other examples.

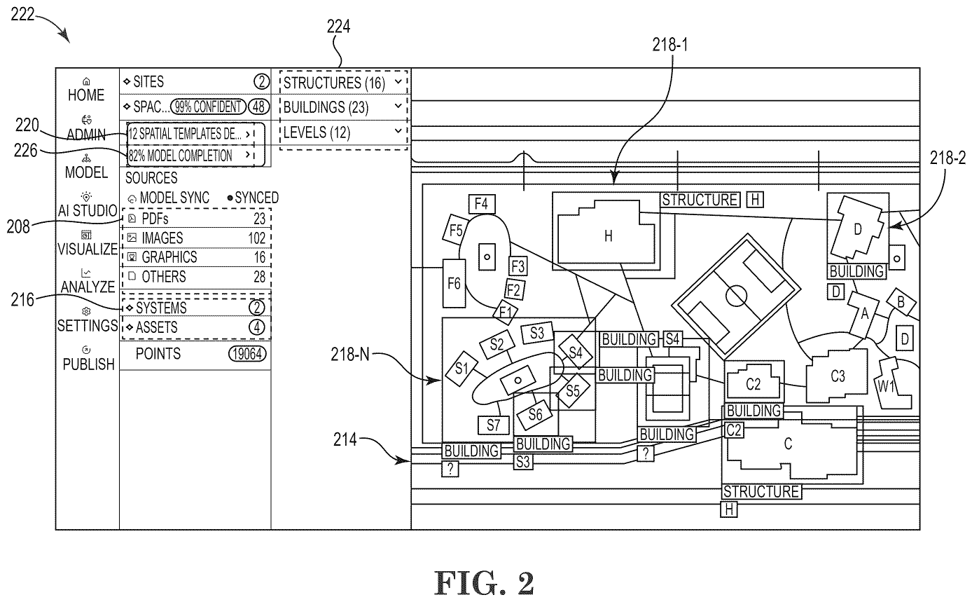

Further, once the spatial model 114 is generated, the spatial model 114 can be displayed on a user interface 122. Inputs can be made to modify the spatial model 114 via the user interface 122, and/or the spatial model 114 can be utilized for building asset management via the user interface 122. An example of the spatial model 114 displayed on a user interface 122 is further described in connection with FIG. 2.

FIG. 2 illustrates an example of a user interface 222 displaying a spatial model 214 in accordance with one or more embodiments. The spatial model 214 can be generated by system 100 (e.g., generative AI model 104), as previously described herein (e.g., in connection with FIG. 1). As illustrated in FIG. 2, the spatial model 214 can include at least models of spaces 218 in the facility and objects 216 in the facility.

The user interface 222 can display the generated spatial model 214. The user interface 222 can be a display of a computing device of a user who may be utilizing the spatial model 214 in a building asset management system, for example.

The spatial model 214 can include models of spaces 218-1, 218-2, 218-N in the facility, which may be collectively referred to herein as models of spaces 218. For example, the facility can be a hospital where space 218-1 is a first building, space 218-2 is a second building, and space 218-N is an N'th building of the hospital. In response to a user selecting the space 218-1, the spatial model 214 can illustrate the geometry of the first building, the number of floors in the first building, the spaces that are in the first building (e.g., conference rooms, offices, waiting rooms, etc.), the dimensions of each of the spaces, etc. Such spaces and/or sub-spaces in the facility can be represented as templates in the spatial model 214.

Additionally, the spatial model 214 can include objects 216 in the facility. While not illustrated in FIG. 2 for clarity, an organized list of the objects 216 included in the spatial model 214 can be displayed. In response to a user selecting the systems and/or assets (e.g., objects 216) via the user interface 222, the user interface 222 can display the assets, the names of the assets, the types of assets, locational relationships with the assets, etc.

As previously described in connection with FIG. 1, a user can upload facility information to the generative AI model in order to generate the spatial model 214. As illustrated in FIG. 2, the user interface 222 can display a summary of the facility information 208 that was uploaded. For example, the summary of the facility information 208 indicates that 23 PDFs were uploaded, 102 images were uploaded, 16 HMI graphics were uploaded, and 26 other files were uploaded as facility information (e.g., the facility layout information such as technical drawings, building plans, etc., as well as the technical asset information such as project documents). In response to a user selecting the summary of the facility information 208 that was uploaded via the user interface 222, the user interface 222 can display the various facility information 208 that was uploaded (e.g., display of the actual PDFs, images, HMI graphics, etc. that were uploaded). For example, if a user selects the facility information 208, the user can view an HMI graphic associated with a plumbing system of the hospital as a piece of facility information 208 that was uploaded to the generative AI model, among other examples.

As illustrated in FIG. 2, the spatial model 214 includes spatial hierarchy data 224. The spatial hierarchy data can indicate the identified spaces in the facility, labeled spaces in the facility, categorized space types of the spaces in the facility, and/or locational relationships between the identified spaces in the facility. As illustrated in FIG. 2, the spatial hierarchy data 224 can include 16 identified structures, 23 identified buildings, 12 levels for a particular building, etc.

In the example illustrated in FIG. 2, the spatial model 214 includes 12 spatial templates 220. In response to a user selecting a spatial template 220 via the user interface 222, the user interface can display the particular spatial template 220 via the user interface 222, including the model of the space (e.g., the model of the operating room) and objects included in the space (e.g., assets that service, are connected to, and/are located in the space).

In some examples, the user interface 222 can receive, from a user, an input to correct the spatial model 214. For example, the generative AI model may have generated the spatial model 214 to include a space that is an office, when in fact the space is actually a conference room. The user can provide an input to the user interface 222 to correct the spatial model 214 such that the space is an updated space type (e.g., re-categorized from an office to a conference room), the space is given a revised name (e.g., Office 2 to Conference Room 3), etc. Additionally, in some examples the relational information can be corrected as well.

As mentioned above, in some examples, a model of a space 218 in a template can be selected on the user interface 222. In response, the user interface 222 can display the facility layout information from the facility information associated with the model of the space. For example, a user can select, via the user interface 222, the model of the space 218-2, and in response, the user interface 222 can display facility layout information such as PDFs, images, HMI graphics, BIM files, etc. associated with the model of the space 218-2 that were uploaded for the generative AI model. For example, upon selecting a particular office, the user interface 222 can display the office on the PDF scan of the architectural drawings that were uploaded to the generative AI model. In such a way, a user can review the facility layout information that was uploaded for the spatial model 214.

Additionally, in some examples, an object 216 in the template can be selected on the user interface 222. In response, the user interface 222 can display the technical asset information from the facility information associated with the object. For example, a user can select, via the user interface 222, a particular object (e.g., a pump), and in response, the user interface 222 can display the project document that was uploaded that included the pump. Similarly, in such a way a user can review the technical asset information that was uploaded for the spatial model 214.

The computing device (e.g., computing device 102, previously described in connection with FIG. 1) can perform an error detection on the spatial model to determine an error level 226 for the spatial model, which can be displayed on user interface 222. For example, the error level can indicate how incomplete the spatial model 214 is determined to be. The error level 226 can be displayed on the user interface 222. For example, as illustrated in FIG. 2, the error level as a description of completeness of the spatial model 214, is determined to be 82% model completion.

As an example, the generative AI model can determine, according to the facility information that was uploaded, that a particular building has five floors, but facility information about four of the floors was provided. Therefore, there is a particular floor that does not have information provided, and therefore the spatial model is partially incomplete.

Upon selecting the error level 226, the user interface 222 can display the portion of the spatial model 214 that is determined to be incomplete. For example, the user interface 222 can display, to a user, the particular floor that does not have information provided for it. A user can provide that information manually, upload information about the floor to the generative AI model, among other actions in order to remedy the incomplete portion for the spatial model 214. The error level 226 can be updated accordingly.

Although the example above is given as a missing floor resulting in an incomplete spatial model, embodiments of the disclosure are not so limited. For example, an incomplete spatial model may be the result of an asset not being detected when it should be (e.g., a compressor not being present when it was included in an HMI graphic), an illogical connection between two objects (e.g., a connection between a pump and a television exists), etc.

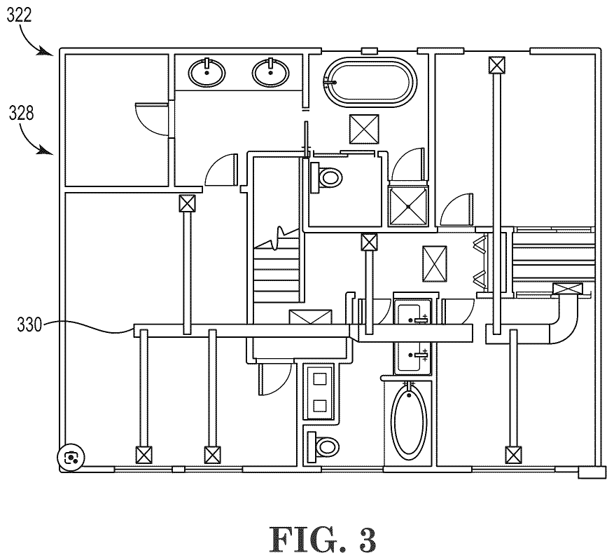

FIG. 3 illustrates an example of a user interface 322 displaying a technical diagram 328 included as facility layout information for generating a spatial model of a facility in accordance with one or more embodiments. As previously described in connection with FIG. 2, in response to a user selecting facility layout information, the user interface 322 can display the technical diagram 328.

The technical diagram 328 can be a building drawing such as an HVAC layout 330 for the HVAC system for a particular space. The HVAC layout 330 can illustrate the HVAC duct work for a particular floor of a building, including supply air and exhaust air flows. The technical diagram 328 can have been included in the facility information uploaded to the generative AI model as part of facility layout information, and can have been included as an image and/or as part of a BIM model, among other examples.

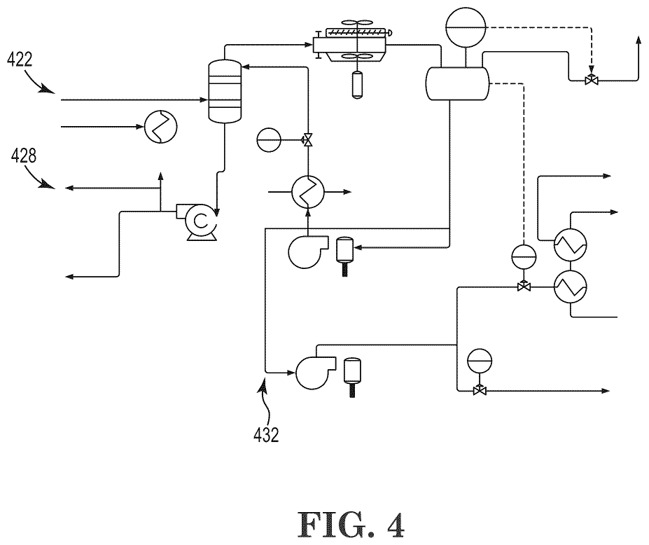

FIG. 4 illustrates an example of a user interface displaying technical diagram included as facility layout information for generating a spatial model of a facility in accordance with one or more embodiments. As previously described in connection with FIG. 2, in response to a user selecting facility layout information, the user interface 322 can display the technical diagram 328.

The technical diagram 428 can be an instrumentation diagram 432 for a heating and cooling system for the facility. The instrumentation diagram 432 can illustrate process equipment associated with the heating and cooling system of the facility, indicating a general flow of process for the heating and cooling system and the interconnection of the heating and cooling devices that make up the system. The technical diagram 428 can have been included in the facility information uploaded to the generative AI model as part of facility layout information, and can have been included as an image and/or as part of an HMI graphic, among other examples.

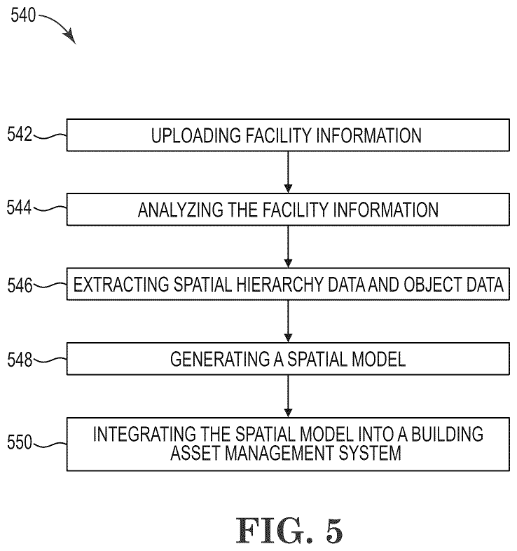

FIG. 5 illustrates an example of a method 540 for generating a spatial model of a facility in accordance with one or more embodiments. The method 540 can be performed by, for example, a computing device 102 and a computing device 107 of system 100, previously described in connection with FIG. 1.

At 542, the method 540 includes uploading, by a first computing device, facility information associated with a facility to a second computing device. The second computing device can be included as part of a cloud computing environment. The facility information can include facility layout information for the facility and technical asset information associated with devices in the facility. The facility layout information can include, for instance, BIM models for the facility, HMI graphics for the facility, and/or building plans for the facility. The technical asset information can include project documents for the devices in the facility.

At 544, the method 540 includes analyzing, by a generative AI model hosted by the second computing device, the facility layout information and the technical asset information. The generative AI model can analyze the facility layout information and the technical asset information using natural language processing and/or image processing techniques.

At 546, the method 540 includes extracting, by the generative AI model, spatial hierarchy data and object data from the analyzed facility layout information and technical asset information, respectively. Extracting the spatial hierarchy data can include identifying spaces in the facility, labeling spaces in the facility, categorizing space types of the spaces in the facility, and/or determining locational relationships between the identified spaces in the facility. Extracting the object data can include identifying assets in the facility, labeling assets in the facility, categorizing asset types in the facility, determining locational relationships between the identified assets and identified spaces in the facility from the spatial hierarchy data, and/or determining connection relationships between the identified assets.

At 548, the method 540 includes generating, by the generative AI model, a spatial model of the facility including instances for the spatial model using the spatial hierarchy data and the object data. The spatial model can include models of spaces in the facility, objects in the facility, and a template for spaces in the facility.

At 550, the method 540 includes integrating, by the second computing device, the spatial model of the facility into a building asset management system of the facility. The building asset management system can allow for monitoring asset performance of the facility, health of the facility, and/or for incident management, among other examples.

FIG. 6 is an example of a computing device 602 for generating a spatial model of a facility in accordance with one or more embodiments. Computing device 602 can be, for instance, computing device 102 previously described in connection with FIG. 1. As illustrated in FIG. 6, the computing device 602 can include a memory 664 and a processor 662 for generating a spatial model of a facility, in accordance with the present disclosure.

The memory 664 can be any type of storage medium that can be accessed by the processor 662 to perform various examples of the present disclosure. For example, the memory 664 can be a non-transitory computer readable medium having computer readable instructions (e.g., executable instructions/computer program instructions) stored thereon that are executable by the processor 662 for generating a spatial model of a facility in accordance with the present disclosure.

The memory 664 can be volatile or nonvolatile memory. The memory 664 can also be removable (e.g., portable) memory, or non-removable (e.g., internal) memory. For example, the memory 664 can be random access memory (RAM) (e.g., dynamic random access memory (DRAM) and/or phase change random access memory (PCRAM)), read-only memory (ROM) (e.g., electrically erasable programmable read-only memory (EEPROM) and/or compact-disc read-only memory (CD-ROM)), flash memory, a laser disc, a digital versatile disc (DVD) or other optical storage, and/or a magnetic medium such as magnetic cassettes, tapes, or disks, among other types of memory.

Further, although memory 664 is illustrated as being located within computing device 602, embodiments of the present disclosure are not so limited. For example, memory 664 can also be located internal to another computing resource (e.g., enabling computer readable instructions to be downloaded over the Internet or another wired or wireless connection).

The processor 662 may be a central processing unit (CPU), a semiconductor-based microprocessor, and/or other hardware devices suitable for retrieval and execution of machine-readable instructions stored in the memory 664.

Although specific embodiments have been illustrated and described herein, those of ordinary skill in the art will appreciate that any arrangement calculated to achieve the same techniques can be substituted for the specific embodiments shown. This disclosure is intended to cover any and all adaptations or variations of various embodiments of the disclosure.

It is to be understood that the above description has been made in an illustrative fashion, and not a restrictive one. Combination of the above embodiments, and other embodiments not specifically described herein will be apparent to those of skill in the art upon reviewing the above description.

The scope of the various embodiments of the disclosure includes any other applications in which the above structures and methods are used. Therefore, the scope of various embodiments of the disclosure should be determined with reference to the appended claims, along with the full range of equivalents to which such claims are entitled.

In the foregoing Detailed Description, various features are grouped together in example embodiments illustrated in the figures for the purpose of streamlining the disclosure. This method of disclosure is not to be interpreted as reflecting an intention that the embodiments of the disclosure require more features than are expressly recited in each claim.

Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method for generating a spatial model of a facility, comprising:
uploading, to a computing device, facility information associated with a facility, wherein the facility information includes:
facility layout information for the facility including building information models for the facility, human-machine interface graphics for the facility, and building plans for the facility; and
technical asset information associated with devices in the facility including project documents for the devices;
analyzing, by a generative artificial intelligence (AI) model hosted by the computing device, the facility layout information and the technical asset information;
extracting, by the generative AI model, spatial hierarchy data and object data from the analyzed facility layout information and technical asset information;
generating, by the generative AI model, a spatial model of the facility including instances for the spatial model using the spatial hierarchy data and the object data; and
integrating, by the computing device, the spatial model of the facility into a building asset management system of the facility.

2. The method of claim 1, wherein the method includes analyzing, by the generative AI model, the facility layout information to determine at least one of:
spaces in the facility;
names of the spaces in the facility;
space types of the spaces in the facility;
dimensions of the spaces in the facility; and
locational relationships between the spaces in the facility.

3. The method of claim 2, wherein the method includes generating the spatial model using the spatial hierarchy data to include models of the spaces in the facility, wherein the models of spaces include the instances for the spatial model including:
the spaces in the facility;
the names of the spaces in the facility;
the space types of the spaces in the facility;
the dimensions of the spaces in the facility; and
the locational relationships between the spaces in the facility.

4. The method of claim 1, wherein the method includes analyzing, by the generative AI model, the technical asset information to determine at least one of:
assets in the facility;
names of assets in the facility;
types of assets in the facility; and
relational information for the assets in the facility.

5. The method of claim 4, wherein the method includes generating the spatial model to include objects in the facility, wherein the objects include the instances for the spatial model including:
the assets in the facility;
the names of assets in the facility;
the types of assets in the facility; and
the relational information for the assets in the facility.

6. The method of claim 1, wherein the method includes analyzing, by the generative AI model, the facility layout information and the technical asset information using natural language processing techniques.

7. The method of claim 1, wherein the method includes analyzing, by the generative AI model, the facility layout information and the technical asset information using image recognition techniques.

8. The method of claim 1, wherein generating the spatial model includes generating templates for the spatial model, wherein:
the templates are computing objects; and
the templates include at least one of models of spaces in the facility and objects in the models of the spaces.

9. The method of claim 1, wherein extracting the spatial hierarchy data includes at least one of:
identifying spaces in the facility;
labeling the spaces in the facility;
categorizing space types of the spaces in the facility; and
determining locational relationships between the identified spaces in the facility.

10. The method of claim 1, wherein extracting the object data includes:
identifying assets in the facility;
labeling assets in the facility;
categorizing asset types in the facility;
determining locational relationships between the identified assets and identified spaces in the facility from the spatial hierarchy data; and
determining connection relationships between the identified assets.

11. A non-transitory computer-readable medium storing instructions executable by a processing resource to cause the processing resource to:
receive facility information associated with a facility, wherein the facility information includes:
facility layout information for the facility including building information models for the facility, human-machine interface graphics for the facility, and building plans for the facility; and
technical asset information associated with devices in the facility including project documents for the devices;
analyze, by a generative artificial intelligence (AI) model, the facility layout information and the technical asset information;
extract, by the generative AI model, spatial hierarchy data and object data from the analyzed facility layout information and the technical asset information;
generate, by the generative AI model, a spatial model of the facility including instances for the spatial model using the spatial hierarchy data and the object data, wherein the spatial model includes:
models of spaces in the facility; and
objects in the facility; and
integrate the spatial model of the facility into a building asset management system of the facility.

12. The non-transitory computer-readable medium of claim 11, wherein the instructions to generate the spatial model include instructions to generate a template for a space in the facility, wherein the template includes a model of the space and objects included in the space.

13. The non-transitory computer-readable medium of claim 11, comprising instructions to cause the processing resource to:
receive, from a user, an input to correct the spatial model; and
correct the spatial model in response to the input being received.

14. The non-transitory computer-readable medium of claim 13, wherein:
the generative AI model is a pre-trained model; and
the processing resource is configured to execute instructions to:
retrain the generative AI model using the generated spatial model; and
retrain the generative AI model based on the correction of the spatial model.

15. The non-transitory computer-readable medium of claim 11, wherein the generative AI model is comprised of a plurality of generative AI model agents such that the processing resource is to:
analyze, by a first generative AI model agent of the plurality of generative AI model agents, the facility layout information and the technical asset information;
extract, by a second generative AI model agent of the plurality of generative AI model agents, the spatial hierarchy data and the object data from the analyzed facility layout information and the technical asset information; and
generate, by a third generative AI model agent of the plurality of generative AI model agents, the spatial model of the facility using the spatial hierarchy data and the object data.

16. A system for generating a spatial model of a facility, comprising:
a user interface;
a processing resource; and
a memory resource storing non-transitory machine-readable instructions to cause the processing resource to:
receive, via the user interface, facility information associated with a facility, wherein the facility information includes:
facility layout information for the facility including building information models for the facility, human-machine interface graphics for the facility, and building plans for the facility; and
technical asset information associated with devices in the facility including project documents for the devices;
analyze, by a generative artificial intelligence (AI) model, the facility layout information and the technical asset information;
extract, by the generative AI model, spatial hierarchy data and object data from the analyzed facility layout information and the technical asset information;
generate, by the generative AI model, a spatial model of the facility including instances for the spatial model using the spatial hierarchy data and the object data, wherein the spatial model includes:
models of spaces in the facility;
objects in the facility; and
a template for a space in the facility, wherein the template includes a model of the space and objects included in the space; and
integrate the spatial model of the facility into a building asset management system of the facility.

17. The system of claim 16, comprising instructions to cause the processing resource to:
perform error detection on the spatial model to determine an error level for the spatial model; and
cause the error level to be displayed on the user interface.

18. The system of claim 17, wherein in response to the error level being selected on the user interface, the processing resource is configured to cause the user interface to display a portion of the spatial model that is incomplete, wherein the error level is associated with the incomplete portion of the spatial model.

19. The system of claim 16, wherein in response to the model of the space in the template being selected on the user interface, the processing resource is configured to cause the user interface to display the facility layout information from the facility information associated with the model of the space.

20. The system of claim 16, wherein in response to the object in the template being selected on the user interface, the processing resource is configured to cause the user interface to display the technical asset information from the facility information associated with the object.
